(19) United States
(12) Patent Application Publication
(10) Pub. No.: US 2024/0387340 A1
(43) Pub. Date: Nov. 21, 2024

(54) Through-Hole Structures for Improved Power Performance

(71) Applicant: Intel Corporation, Santa Clara, CA (US)

(72) Inventors: Jaydeep Ramniklal PARMAR, Gujarat (IN); Pali BARMATE, Balaghat (IN); Tamilarasi PONNUSAMY, Namakkal (IN)

(21) Appl. No.: 18/318,755

(22) Filed: May 17, 2023

(51) Int. Cl. H01L 23/498; H01L 21/48

(52) U.S. Cl. CPC H01L 23/49827; H01L 21/4857; H01L 21/486; H01L 23/49822

(57) ABSTRACT

The present disclosure is directed to a package substrate having surface layers with a power region for coupling with a semiconductor device, base layers of the package substrate, and a plurality of through hole vias providing direct couplings between the surface layers with the base layers, for which the surface layers and the base layer are provided with micro vias and the plurality of through hole vias are located below the power region of the surface layer. In an aspect, the package substrate includes a first and second plurality of plane layers, for which the first and second plurality of plane layers are without micro vias.

### BACKGROUND

For integrated circuit design and fabrication, the need to improve performance and lower costs are constant challenges. As transistors continue to shrink in size, it is becoming more and more difficult and costly to realize high-volume manufacturing for semiconductors. Cost savings may be potentially realized by building more efficient structures that improve power performance.

It is, however, increasingly common to use micro vias as the interconnects between layers in high-density interconnect package substrates to accommodate the high input/output (I/O) density of advanced packages. These advanced packages may require more power plane area and multiple split power planes in multiple layers for critical and high-current power rails. It is therefore important to have connectivity solutions that can improve connectivity for advanced packages, decrease form factors, and reduce impedance and inductance effects.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary cross-section view of a through hole via structure, which is a section from FIG. 1A, according to an aspect of the present disclosure;

FIGS. 2A and 2B show a comparison between exemplary cross-section views of through hole via structures according to an aspect of the present disclosure;

FIGS. 3A and 3B show a comparison between exemplary representation of a typical multi-layered through hole and micro via structures and a present through hole structure according to an aspect of the present disclosure;

FIG. 4 shows an exemplary cross-section representation of a test circuit pathway through a semiconductor package and two through hole vias according to an aspect of the present disclosure; and

FIG. 5 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure relates to a solution that provides “solid” connectivity between, for example, base layers (n-2) and surface layers (n-2) of a package substrate using through hole via structures in a “power region” (i.e., the region/area below or in the “shadow” of a semiconductor die or device). To remove the effects caused by traces and different via sizes, the present through hole via structures may be used in place of staggered micro vias and provide solid connections between the semiconductor device and, for example, a land grid array (LGA) or ball grid array (BGA). In an aspect, by using larger vias directly under the semiconductor device, the present through hole vias may reduce the impedance discontinuities and improve the connectivity between the semiconductor device and a BGA.

The present disclosure is directed to a package substrate including surface layers with a power region for coupling with one or more semiconductor devices, base layers, a core layer with top and bottom surfaces placed between the surface and base layers, and a plurality of through hole vias providing direct couplings between the surface layers (n-2) with the base layers (n-2). The plurality of through hole vias may be located below the power region of the surface layers.

The present disclosure is also directed to a method that includes providing a core layer having top and bottom surfaces to build a package substrate. Thereafter, in this method, forming a first plurality of plane layers on the top surface of the core layer and a second plurality of plane layers on the bottom surface of the core layer, for which the first and second plurality of plane layers are without micro vias. Further to this method, forming a plurality of through vias through the first plurality of plane layers, the core layer, and the second plurality of plane layers. Further to this method, forming surface layers on the first plurality of plane layers and a first plurality of micro vias in the surface layers. Further to this method, forming base layers on the second plurality of plane layers and a second plurality of micro vias in the base layers to form the package substrate.

In another aspect, the present disclosure is directed to an electronic component having a semiconductor device, a package substrate having surface layers with a first plurality of micro vias for coupling with the semiconductor device, a core layer, base layers with a second plurality of micro vias, a first plurality of plane layers without micro vias positioned between the surface layers (n-2) and the core layer, a second plurality of plane layers without micro vias positioned between the core layer and the base layers (n-2), and a plurality of through hole vias located below the semiconductor device that passes through the first and second plurality of plane layers and the core layer and couple the surface layers (n-2) with the base layers (n-2).

The technical advantages of the present disclosure include, but are not limited to:
(i) Providing enhanced performance of critical and high current power rails in a package substrate;
(ii) Providing reduced resistivity/impedance effects; and
(iii) Providing decreased form factors (e.g., layer count) for electronic components.

To more readily understand and put into practical effect the present structures and method leading to the reduced use of micro vias, which may be used for electronic component manufacturing to improve yield and performance, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

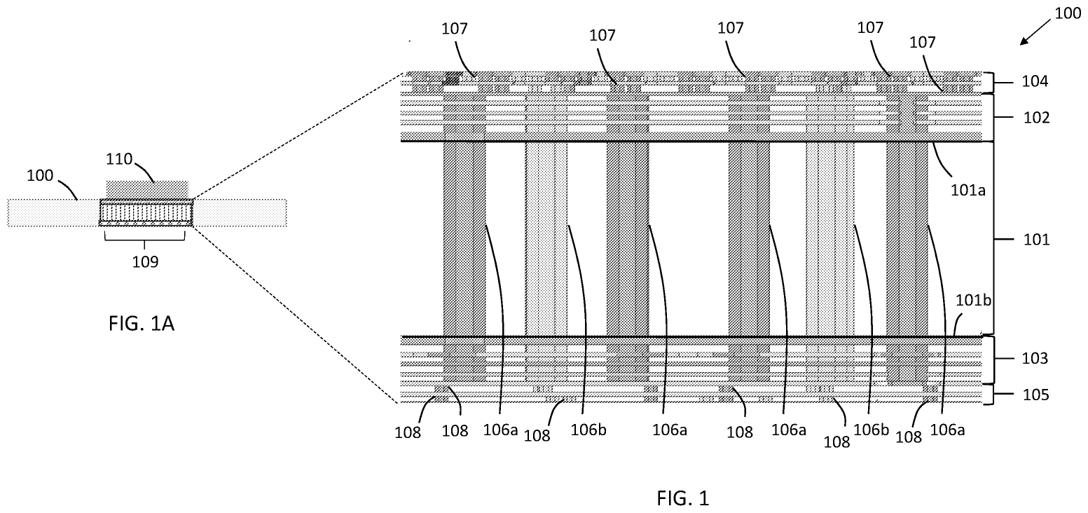

In FIG. 1, an exemplary cross-section view of a through hole via structure is shown for a package substrate 100 according to an aspect of the present disclosure. In this aspect, the package substrate 100 may have a core layer 101, which may be a substrate that is made of rigid materials or is made of a multi-layered stack of conductive and dielectric materials. In addition, the package substrate 100 may have a first plurality of plane layers 102 on a top surface 101a of the core layer 101, and a second plurality of plane layers 103 on a bottom surface 101b of the core layer 101. The first and second plurality of plane layers 102 and 103 may include conductive and non-conductive layers, including signal layers and ground layers. According to the present disclosure, the first and second plurality of plane layers 102 and 103 should not have any micro vias formed therein.

In another aspect, the package substrate 100 may have surface layers 104 positioned over the first plurality of plane layers 102, and base layers 105 positioned over the second plurality of plane layers 103. In addition, a plurality of through hole vias 106a and 106b may be positioned between the surface layers 104 (n-2) and the base layers 105 (n-2) to electrically connect them as “direct couplings”, i.e., without the use of two or more separately forms vias that may need to be aligned or will otherwise be staggered. It should be understood that surface layers 104 and base layers 105 may have a greater (or lesser) number of layers than shown; for example, the electrical connection may be between surface layers (n-3) and base layers (n-3). In addition, the surface layers 102 may have a greater or lesser number of layers than the base layers; for example, the electrical connection may be between the surface layers (n-2) and the base layers (n-3).

As shown in FIGS. 1 and 1A, the surface layers 104 may have a first plurality of micro vias 107, which may be used as interconnects and to couple the package substrate 100 to a semiconductor die/device or package 110, and the base layers 105 may have a second plurality of micro vias 108, which may be used as interconnects between the layers of the base layers and to electrically couple with a printed circuit board.

According to the present disclosure, the plurality of through hole vias 106a and 106b may be positioned directly under or below the semiconductor die/device or package 110, which may be considered to be a “power region” 109 of the package substrate 100, as shown in FIG. 1A. In an aspect, one or more of the plurality of through hole vias 106a may provide power connections and one or more of the plurality of through hole vias 106b may provide ground connections. In another aspect, the dimensions of the plurality of through hole vias 106a and 106b may be dependent on the layout for the package substrate 100 and the semiconductor device attached thereto. For example, based on modeling analysis, when using a commercially available core material, such as R1515V, the plurality of through hole vias 106a and 106b may have a diameter of approximately 265 μm and the through hole vias may have a length of approximately 1149 μm. It should be understood that the dimensions of the through hole vias will depend on the core material being used as well as the thickness of a package substrate.

In another aspect, one or more of the plurality of through hole vias 106a and 106b may be coupled to one or more of the first plurality of plane layers 102 and one or more of the plurality of through hole vias 106a and 106b may be coupled to one or more of the second plurality of plane layers 103. It should be understood that the plurality of through hole vias 106a and 106b is directed primarily to plated through hole vias.

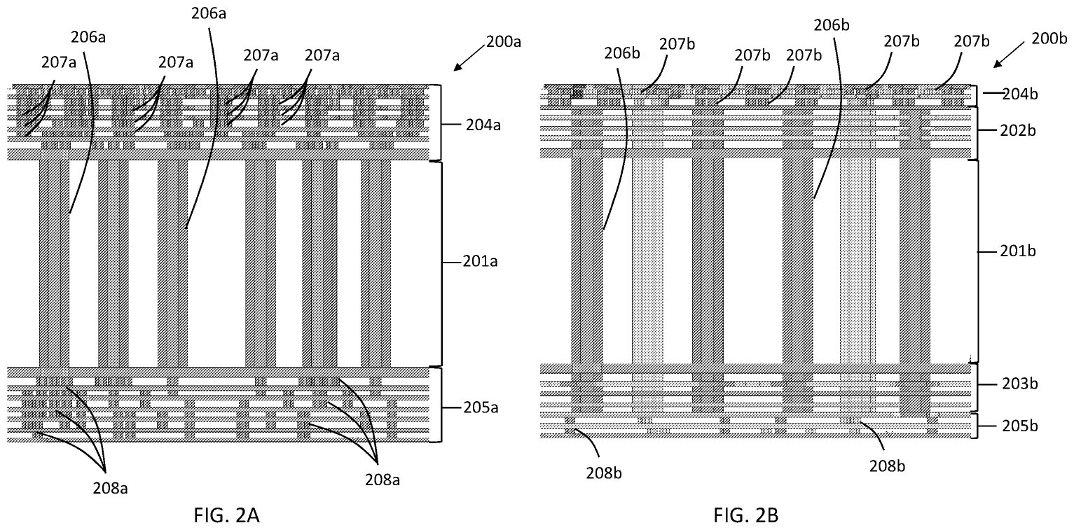

In FIGS. 2A and 2B, a conventional package substrate 200a is shown as a basis for comparison with a present package substrate 200b as cross-section views of their respective through hole via structures. As shown in FIG. 2A, the package substrate 200a has a core layer 201a with surface layers 204a and base layers 205a. The surface layers 204a have a first plurality of micro vias 207a, which are staggered vertically to provide interconnection between the layers, and base layers 205a have a second plurality of micro vias 208a, which are also staggered vertically to provide interconnection between the layers and are connected by through hole vias 206a.

As shown in FIG. 2B, the package substrate 200b may have a core layer 201b, a first plurality of plane layers 202b on a top surface of the core layer 201b, and a second plurality of plane layers 203b on a bottom surface of the core layer 201b. According to the present disclosure, similar to the package substrate 100 in FIG. 1, the first and second plurality of plane layers 202b and 203b should not have any micro vias formed therein. The package substrate 200b may have surface layers 204b positioned over the first plurality of plane layers 202b, and base layers 205b positioned over the second plurality of plane layers 203b. In addition, a plurality of through hole vias 206b may be positioned, as shown in FIG. 2B, between the surface layers 204b (n-2) and the base layers 205b (n-2) to electrically couple them. In this aspect, the surface layers 204b may have a first plurality of micro vias 207b, and the base layers 205b may have a second plurality of micro vias 208b.

As shown in the comparison between FIGS. 2A and 2B, the through hole vias 206b are longer than the through hole vias 206a, which allows for a more direct electrical pathway between the top surface (n-2) and bottom surface (n-2) of the package substrate 200b. In addition, the reduced need for micro vias will simplify the manufacturing of a package substrate, as well as reduce costs.

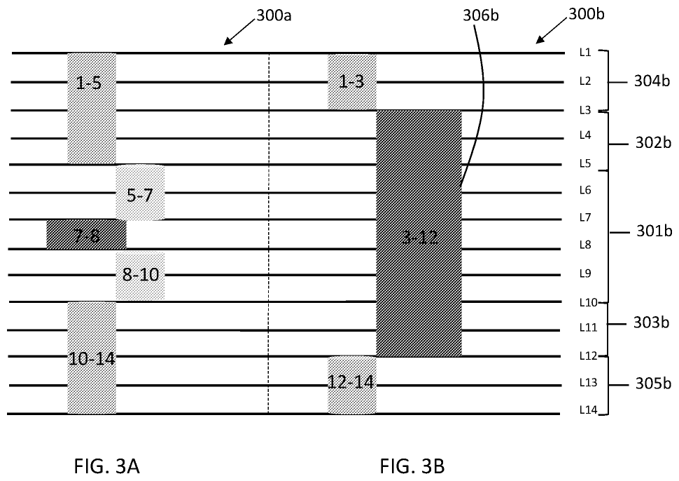

FIGS. 3A and 3B show a comparison between exemplary representations of a typical multi-layered micro via structure for a package substrate 300a and a present through hole via structure for a package substrate 300b according to an aspect of the present disclosure. The layers L1 through L14 represent typical routing/signal lines and planes that are used in package substrates. As shown in FIG. 3A, the package substrate 300A has interconnects between the layers L1 through L14 provided by vias (i.e., through hole and micro vias) that are provided in staggered alignments.

As shown in FIG. 3B, the package substrate 300b may have a multi-layered core section 301b, a first plurality of plane layers 302b on a top surface of the core layer 301b, and a second plurality of plane layers 303b on a bottom surface of the core layer 301b. The first and second plurality of plane layers 302b and 303b should not have any micro vias formed therein. The package substrate 300b may have surface layers 304b positioned over the first plurality of plane layers 302b, and base layers 305b positioned over the second plurality of plane layers 303b. In addition, a through hole vias 306b may be positioned between an L2 of surface layers 304b and an L12 of base layers 305b to electrically couple them. Similar to the comparison between FIGS. 2A and 2B, the through hole via 306b are longer than the package substrate 300a interconnects, which allows for a more direct electrical pathway between the top and bottom surfaces of the package substrate 300b. In addition, the reduced need for micro vias will simplify the manufacturing of a package substrate, as well as reduce costs.

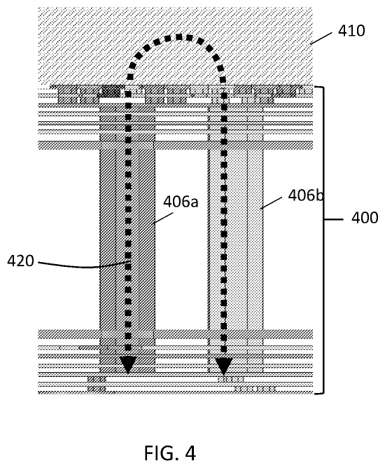

FIG. 4 shows an exemplary cross-section representation of a test circuit pathway 420 through a semiconductor package 410 and two through hole vias 406a and 406b in a segment of a package substrate 400 with multiple sets of through hole vias according to an aspect of the present disclosure. In an aspect, by using larger vias directly under the semiconductor package 410, the present through hole vias 406a and 406b may reduce the impedance discontinuities and improve the connectivity between the semiconductor device and a BGA. In simulations, a measurement of the test circuit pathway 420 (i.e., a via loop from power to ground) from the semiconductor package 410 to BGA pin (not shown) for the resistance and inductance. For example, in a simulation, the multiple sets of vias 406a and 406b, which were provided a diameter of 265 μm, produced a resistance of R=8.486 mohm and an inductance of L=0.1176 nH, as compared with a resistance of R=7.489 mohm and an inductance of L=0.139 nH for a staggered via structure. It should be understood that the foregoing resistance and inductance values were taken for a representative unit (2 mm×2 mm) of the power region.

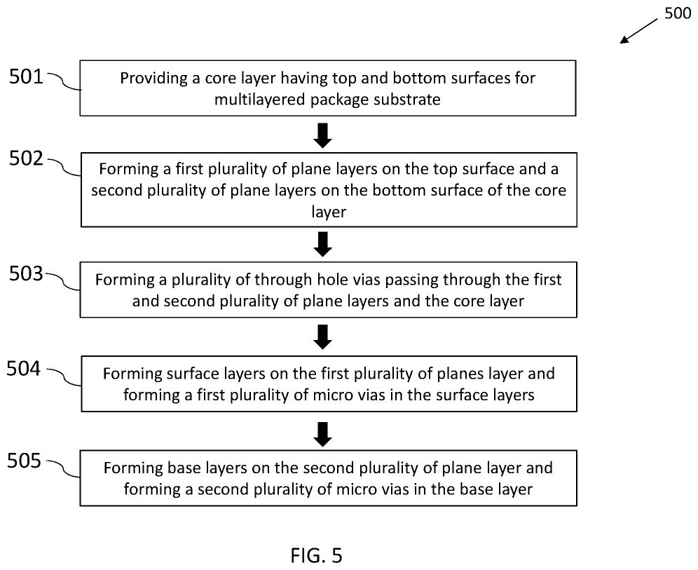

FIG. 5 shows a simplified flow diagram for an exemplary method 500 according to an aspect of the present disclosure.

The operation 501 may be directed to providing a core layer having top and bottom surfaces for a multilayered package substrate.

The operation 502 may be directed to forming a first plurality of plane layers on the top surface and a second plurality of plane layers on the bottom surface of the core layer.

The operation 503 may be directed to forming a plurality of through hole vias passing through the first and second plurality of plane layers and the core layer.

The operation 504 may be directed to forming surface layers on the first plurality of planes layer and forming a first plurality of micro vias in the surface layers.

The operation 505 may be directed to forming base layers on the second plurality of plane layer and forming a second plurality of micro vias in the base layer.

The power delivery of a package substrate is considered critical for high-speed system performance as devices are becoming more sensitive to the power ground noise from the board and package. As shown by the present disclosure, solutions that provide solid connectivity between base layers and surface layers of a package substrate using through hole via structures under the shadow of a semiconductor die or device may reduce the impedance and improve the connectivity between the semiconductor device and a land grid array (LGA) or ball grid array (BGA). To improve the electrical performance of the package, the present through hole via structures can replace staggered vias structures and reduce the impedance discontinuities caused by traces and different via sizes.

It will be understood that any property described herein for a particular package substrate structure according to the present disclosure may also hold for any electronic component using such package substrate structure described herein. It will also be understood that any property described herein for a specific method may hold for any of the methods described herein. Furthermore, it will be understood that for any particular package substrate structure and the methods described herein, not necessarily all the components or operations described will be shown in the accompanying drawings or method, but only some (not all) components or operations may be disclosed.

To more readily understand and put into practical effect the present semiconductor carrier platforms and thermal stability layers, they will now be described by way of examples. For the sake of brevity, duplicate descriptions of features and properties may be omitted.

### EXAMPLES

Example 1 provides a package substrate including surface layers with a power region for coupling with a semiconductor device, base layers, a core layer with top and bottom surfaces between the surface and base layers, and a plurality of through hole vias providing direct couplings between the surface layers with the base layers, for which the plurality of through hole vias are located in the power region below the semiconductor device positioned over the surface layers.

Example 2 may include the package substrate of example 1 and/or any other example disclosed herein, for which the surface layers comprise a first plurality of micro vias coupling the surface layers.

Example 3 may include the package substrate of example 1 and/or any other example disclosed herein, for which the base layers comprise a second plurality of micro vias coupling the base layers.

Example 4 may include the package substrate of example 1 and/or any other example disclosed herein, for which the through-hole vias extend through the top surface of the core layer to the surface layers and extend below the bottom surface of the core layer to the base layers.

Example 5 may include the package substrate of example 4 and/or any other example disclosed herein, which further includes a first plurality of plane layers positioned between the top surface of the core layer and the surface layers.

Example 6 may include the package substrate of example 5 and/or any other example disclosed herein, for which the first plurality of plane layers are without micro vias.

Example 7 may include the package substrate of example 4 and/or any other example disclosed herein, which further includes a second plurality of plane layers positioned between the bottom surface of the core layer and the base layers.

Example 8 may include the package substrate of example 7 and/or any other example disclosed herein, for which the second plurality of plane layers are without micro vias.

Example 9 may include the package substrate of example 5 and/or any other example disclosed herein, for which the through hole vias couple one or more of the first plurality of plane layers with the surface layers.

Example 10 may include the package substrate of example 7 and/or any other example disclosed herein, for which the through hole vias couple one or more of the second plurality of plane layers with the base layers.

Example 11 may include the package substrate of example 1 and/or any other example disclosed herein, for which one or more of the through hole vias provide a power coupling between the surface and base layers.

Example 12 may include the package substrate of example 1 and/or any other example disclosed herein, for which one or more of the through hole vias provide a ground coupling between the surface and base layers.

Example 13 provides a method that includes providing a core layer for a package substrate, for which the core layer has a top surface and a bottom surface, forming a first plurality of plane layers on the top surface of the core layer, forming a second plurality of plane layers on the bottom surface of the core layer, forming a plurality of through vias through the first plurality of plane layers, the core layer, and the second plurality of plane layers, forming surface layers on the first plurality of plane layers, forming a first plurality of micro vias in the surface layers, forming base layers on the second plurality of plane layers, and forming a second plurality of micro vias in the base layers, for which the first and second plurality of plane layers are formed without micro vias.

Example 14 may include the method of example 13 and/or any other example disclosed herein, for which the plurality of through hole vias couples the surface and base layers.

Example 15 may include the method of example 13 and/or any other example disclosed herein, for which the plurality of through vias provides power and ground couplings for a semiconductor device coupled to the surface layers.

Example 16 provides an electronic component including a semiconductor device, a package substrate including surface layers with a first plurality of micro vias for coupling with the semiconductor device, a core layer, base layers with a second plurality of micro vias, a first plurality of plane layers without micro vias positioned between the surface layers and the core layer, a second plurality of plane layers without micro vias positioned between the core layer and the base layers, and a plurality of through hole vias located below the semiconductor device that passes through the first and second plurality of plane layers and the core layer and couple the surface layers with the base layers.

Example 17 may include the electronic component of example 16 and/or any other example disclosed herein, for which the through hole vias couples one or more of the first plurality of plane layers with the surface layers.

Example 18 may include the electronic component of example 16 and/or any other example disclosed herein, for which the through hole vias couples one or more of the second plurality of plane layers with the base layers.

Example 19 may include the electronic component of example 16 and/or any other example disclosed herein, for which one or more of the through hole vias provides power couplings between the semiconductor device and the base layer.

Example 20 may include the electronic component of example 16 and/or any other example disclosed herein, for which one or more of the through hole vias provides ground couplings between the semiconductor device and base layer.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A package substrate comprising:
surface layers with a power region for coupling with a semiconductor device;
base layers;
a core layer with a top surface and a bottom surface, wherein the core layer is disposed between the surface layers and the base layers; and
a plurality of through hole vias providing direct couplings between the surface layers with the base layers, wherein the plurality of through hole vias are located in the power region below the semiconductor device positioned over the surface layers.

2. The package substrate of claim 1, wherein the surface layers comprise a first plurality of micro vias coupling the surface layers to each other.

3. The package substrate of claim 1, wherein the base layers comprise a second plurality of micro vias coupling the base layers to each other.

4. The package substrate of claim 1, wherein the through hole vias extend through the top surface of the core layer to the surface layers and extend below the bottom surface of the core layer to the base layers.

5. The package substrate of claim 4, further comprises a first plurality of plane layers positioned between the top surface of the core layer and the surface layers.

6. The package substrate of claim 5, wherein the first plurality of plane layers is without micro vias.

7. The package substrate of claim 4, further comprises a second plurality of plane layers positioned between the bottom surface of the core layer and the base layers.

8. The package substrate of claim 7, wherein the second plurality of plane layers are without micro vias.

9. The package substrate of claim 5, wherein the through hole vias couple one or more of the first plurality of plane layers with the surface layers.

10. The package substrate of claim 7, wherein the through hole vias couple one or more of the second plurality of plane layers with the base layers.

11. The package substrate of claim 1, wherein one or more of the through hole vias provide a power coupling between the surface layers and the base layers.

12. The package substrate of claim 1, wherein one or more of the through hole vias provide a ground coupling between the surface layers and the base layers.

13. A method comprising:
providing a core layer for a package substrate, wherein the core layer has a top surface and a bottom surface;
forming a first plurality of plane layers on the top surface of the core layer;
forming a second plurality of plane layers on the bottom surface of the core layer;
forming a plurality of through vias through the first plurality of plane layers, the core layer, and the second plurality of plane layers, wherein the first and second plurality of plane layers are formed without micro vias;
forming surface layers on the first plurality of plane layers;
forming a first plurality of micro vias in the surface layers;
forming base layers on the second plurality of plane layers; and
forming a second plurality of micro vias in the base layers.

14. The method of claim 13, wherein the plurality of through hole vias electrically couples the surface layers to the base layers.

15. The method of claim 13, further comprises coupling a semiconductor device to the surface layers, wherein the plurality of through vias provides power and ground couplings for the semiconductor device coupled to the surface layers.

16. An electronic component comprising:
a semiconductor device;
a package substrate comprising:
surface layers with a first plurality of micro vias for coupling with each other and to the semiconductor device, wherein the semiconductor device is positioned over the surface layers;
a core layer;
base layers with a second plurality of micro vias for coupling with each other;
a first plurality of plane layers without micro vias positioned between the surface layers and the core layer;
a second plurality of plane layers without micro vias positioned between the core layer and the base layers; and
a plurality of through hole vias located below the semiconductor device that passes through the first and second plurality of plane layers and the core layer and couples the surface layers with the base layers.

17. The electronic component of claim 16, wherein the through hole vias couple one or more of the first plurality of plane layers with the surface layers.

18. The electronic component of claim 16, wherein the through hole vias couple one or more of the second plurality of plane layers with the base layers.

19. The electronic component of claim 16, wherein one or more of the through hole vias provide power couplings between the semiconductor device and the base layers.

20. The electronic component of claim 16, wherein one or more of the through hole vias provide ground couplings between the semiconductor device and the base layers.
